(19) United States
(12) Patent Application Publication
(10) Pub. No.: US 2002/0037652 A1
(43) Pub. Date: Mar. 28, 2002

(54) Semiconductor device manufacturing apparatus and method for manufacturing a semiconductor device

(76) Inventors: Tsuyoshi Moriya, Tokyo (JP); Natsuko Ito, Tokyo (JP); Fumihiko Uesugi, Tokyo (JP)

Correspondence Address: Rosenman & Colin LLP, 575 Madison Avenue, New York, NY, 10022-2585, US

(21) Appl. No.: 09/962,169

(22) Filed: Sep. 24, 2001

(30) Foreign Application Priority Data
Sep. 25, 2000 (JP) 2000-290633

(51) Int. Cl. H01L 21/461

(52) U.S. Cl. 438/716

(57) ABSTRACT

In a semiconductor manufacturing apparatus, when an electrostatic chucking voltage for holding a semiconductor substrate to a stage is applied, a deposited film or foreign matter attached to the stage is subjected to electrostatic stress, causing peeling thereof and the generation of particles. To solve this problem, a vacuum suction path is provided having an aperture within a region above the stage immediately below the semiconductor substrate when the semiconductor substrate is fixed thereunto, and the semiconductor substrate is held onto the stage by suction of air from within the suction path, thereby enabling holding of the semiconductor substrate without the application of an electrostatic chucking voltage, making it possible to suppress the generation of particles caused by an electrostatic stress, thereby reducing the number of generated particles.

### BACKGROUND OF THE INVENTION

1. Field of the Invention

The present invention relates to a semiconductor device manufacturing apparatus and a method for manufacturing a semiconductor device, and more particularly to a semiconductor device manufacturing apparatus having a function for preventing the occurrence of impurities (referred to hereinafter as particles) within a process apparatus during the execution of a manufacturing process.

2. Related Art

In the process of manufacturing an LSI device, particles occurring within a process apparatus can become attached to a wafer being processed, this representing a major factor in lowering the product yield, and reducing the up-time of the manufacturing apparatus. These particles occur when reactive matter (deposited film) attached to the inside of a process apparatus flakes off, or when reactive matter grows within the plasma in a process apparatus. Proposed methods of preventing such particles from falling onto the substrate being processed, as noted in the Japanese Unexamined patent publication (KOKAI) No. 5-29272 and the Japanese Unexamined patent publication (KOKAI) No. 7-58033, include a method of mounting a cover after a process is completed, so as to cover the substrate being processed.

FIG. 18 of the accompanying drawings shows a schematic cross-sectional view of a general semiconductor manufacturing apparatus. This semiconductor manufacturing apparatus has a processing chamber 107, into which a semiconductor substrate 101 can be placed, via a gate valve 109. The processing chamber 107 is provided with an intake port 110 for the introduction of processing gas for etching and the like, and a an exhaust port 111 for exhausting the inside of the processing chamber 107. A processing gas introduction path is disposed from the input port 110 in the direction of the semiconductor substrate 106, so that it guides the processing gas to the processed surface substantially uniformly.

At the top and bottom inside the processing chamber are provided an upper electrode 102 for supply of high-frequency (RF) electrical power, and a lower processing electrode 103, respectively. The upper processing electrode 103 is connected to the high-frequency electrode 104, and the lower processing electrode 103 is grounded. On the upper processing electrode 103 a stage 105, on which the semiconductor substrate 101 is placed, is provided so as to sandwich an insulator 108 between it and the lower processing electrode 103. The stage 105 can be moved upward and downward to an appropriate position for processing.

The stage 105 has connected to it an electrostatic chucking power supply 112, this serving as an electrostatic chuck electrode, which holds the semiconductor substrate 101 with the force of static electricity. In a semiconductor manufacturing apparatus for processing a semiconductor substrate, in which RF power is applied so as to generate a plasma, there is normally a negative-potential self-bias generated on the surface of the semiconductor substrate during the generation of the plasma. For this reason, the electrostatic holding (chucking) is usually done by applying a positive potential to the stage 105.

In a semiconductor manufacturing apparatus as described above, an electrostatic chucking voltage is applied to the stage 105 in order to hold the semiconductor substrate 101, and when the electrostatic chucking voltage is applied, an electrostatic stress is generated in the area surrounding the semiconductor substrate 101, thereby leading to the generation of unwanted particles.

Accordingly, it is an object of the present invention to solve the above-noted problems present in a semiconductor manufacturing apparatus of the past, by providing a novel semiconductor manufacturing apparatus and semiconductor manufacturing method in which, by suppressing the generation of electrostatic stress accompanying application of an electrostatic chucking voltage, it is possible to reduce the occurrence of particles within the semiconductor manufacturing apparatus.

### SUMMARY OF THE INVENTION

To achieve the above-noted objects, a first aspect of the present invention is a semiconductor manufacturing apparatus having a processing chamber, which is substantially hermetically sealable in order to maintain a clean condition therewithin, and a stage disposed within the processing chamber, on which is placed a semiconductor substrate that is to be subjected to processing, wherein the semiconductor substrate is fixed on the stage when it is subjected to prescribed processing, the apparatus further having a suction path with an aperture within a region on the stage directly below the semiconductor substrate when the semiconductor substrate is placed thereon, and a suction pump capable of reducing the pressure within the suction path to a pressure that is lower than the pressure within the processing chamber during processing.

By adopting the above-noted configuration, it is possible to fix the semiconductor substrate without using electrostatic suction, and because there are no particles generated by application of an electrostatic chucking voltage, it is possible to reduce the generation of particles.

A second aspect of the present invention is a semiconductor manufacturing apparatus having a processing chamber, which is substantially hermetically sealable in order to maintain a clean condition therewithin, a stage disposed within the processing chamber, on which is placed a semiconductor substrate that is to be subjected to processing, and an electrostatic chucking power supply applying an electrostatic chucking voltage to the stage so as to generate an electrostatic force, which fixes the semiconductor substrate onto the stage, wherein the electrostatic chucking power supply applies an electrostatic chucking voltage that is close to a potential of the semiconductor substrate being processed and within a voltage that enables suction chucking of the semiconductor substrate to the stage by electrostatic force.

By adopting the above-noted configuration, it is possible to suppress electrostatic stress generated when an electrostatic chucking voltage is applied, thereby suppressing the generation of particles. In particular, it is possible to make the electrostatic chucking voltage the same polarity as the self-bias voltage generated at the semiconductor substrate, that is, a negative voltage.

A third aspect of the present invention is a semiconductor manufacturing apparatus having a processing chamber, which is substantially hermetically sealable in order to maintain a clean condition therewithin, a stage disposed within the processing chamber, on which is placed a semiconductor substrate that is to be subjected to processing, an electrostatic chucking power supply applying an electrostatic chucking voltage to the stage so as to generate an electrostatic force, which fixes the semiconductor substrate onto the stage, a processing gas introduction means for introducing a processing gas into within the processing chamber, a lower processing electrode disposed at the bottom part of the processing chamber and for supplying electric power so as to generate plasma from the processing gas, and an upper processing electrode disposed in opposition to the lower processing electrode at the top part of the processing chamber, and a controller performing control so that an electrostatic chucking voltage is applied at a time when a prescribed period of time had passed from the time of the start of supply of the plasma.

In this manner, by shifting the timing of application of the electrostatic chucking voltage with respect to the timing of the supply of power that generates a plasma, it is possible to suppress electrostatic stress generated when the electrostatic chucking voltage is applied, thereby suppressing the generation of particles.

It is possible to embody the present invention as a combination of the third aspect with the second aspect, thereby achieving synergy in suppressing the generation of particles.

A fourth aspect of the present invention is a semiconductor manufacturing apparatus having a processing chamber, which is substantially hermetically sealable in order to maintain a clean condition therewithin, a stage disposed within the processing chamber, on which is placed a semiconductor substrate that is to be subjected to processing, an electrostatic chucking power supply applying an electrostatic chucking voltage to the stage so as to generate an electrostatic force that holds a semiconductor substrate to the stage, and a controller, which applies an electrostatic chucking voltage so that the potential of the stage rises gradually.

In this manner, by raising the potential gradually, rather than applying the electrostatic chucking voltage all at once, it is possible to suppress an electrostatic stress generated when the electrostatic chucking voltage is applied, thereby suppressing generation of particles.

The fourth aspect of the present invention can be combined with the second aspect and the third aspect, thereby achieving synergy in suppressing the generation of particles.

A fifth aspect of the present invention is a semiconductor manufacturing apparatus according to any of the second to fourth aspects of the present invention, wherein electrical power that generates a plasma is made the minimum power necessary to perform processing of a semiconductor substrate, thereby suppressing an electrostatic stress generated when an electrostatic chucking voltage is applied, and suppressing generation of particles.

A sixth aspect of the present invention is a semiconductor manufacturing apparatus having a processing chamber, which is substantially hermetically sealable in order to maintain a clean condition therewithin, a stage disposed within the processing chamber, on which is placed a semiconductor substrate that is to be subjected to processing, and an electrostatic chucking power supply applying an electrostatic chucking voltage to the stage so as to generate an electrostatic force, which fixes the semiconductor substrate onto the stage, wherein on a surface of the stage,there is provided with a film having a composition that is substantially the same as the composition of a particle expected to be generated is formed on a surface of the stage.

The electrostatic stress generated when the electrostatic chucking voltage is applied to the stage is generated by a difference in the dielectric constant of the stage and that of deposited foreign matter attached thereto. Because of this situation, by providing on the stage a film made of a substance having substantially the same composition as a deposited foreign matter attached to the stage, it is possible to reduce the electrostatic stress applied to the deposited film or foreign matter and to suppress the generation of particles.

In particular, in a semiconductor manufacturing apparatus in which tungsten plasma etching is performed, because the generated particles include a large amount of titanium therin, using this type of semiconductor manufacturing apparatus, by making the film material titanium, it is possible to suppress the generation of particles.

A sixth aspect of the present invention is a combination of the second to the fifth aspects, thereby resulting in synergy in suppressing the generation of particles.

In a seventh aspect of a semiconductor manufacturing apparatus according to the present invention, the stage itself is made of a material having a composition that is substantially the same as the composition of particles expected to be generated, the result being that it is possible to suppress generation of particles in the same manner as in the sixth aspect. In particular, in a semiconductor manufacturing apparatus in which tungsten plasma etching is performed, by making the stage material tungsten, it is possible to suppress generation of particles.

It is possible to combine the seventh aspect of the present invention with any of the second to fifth aspects, thereby achieving synergy in suppressing generation of particles.

In an eighth aspect of the present invention, at least the surface material of the stage has a dielectric constant that is substantially the same as the dielectric constant of particles expected to be generated.

As described above, electrostatic stress generated when an electrostatic chucking voltage is applied to the stage is generated by a difference in dielectric constants between the stage and a deposited film or foreign matter thereon, so that even if at least the surface of the stage is made of a material different from the deposited film or foreign matter, if the these are made materials having substantially the same dielectric constant, it is possible to achieve suppression of electrostatic stress.

The eighth aspect of the present invention can be combined with any one of the second to fifth aspects, thereby achieving synergy in suppressing generation of particles.

A method for manufacturing a semiconductor device according to the present invention has a step of placing a semiconductor substrate onto a stage within a processing chamber that can be substantially hermetically sealed in order to maintain a clean condition therewithin, and a step of performing electrostatic chucking of the semiconductor substrate onto the stage, by applying an electrostatic chucking voltage to the stage, wherein in the electrostatic chucking step a electrostatic chucking voltage as close as possible to a potential of the semiconductor substrate being processed and within a voltage that enables suction chucking of the semiconductor substrate onto the stage is applied. In particular, the electrostatic chucking voltage is a negative voltage.

This embodiment of the present invention further has a step of introducing a processing gas into the processing chamber, and a step of generating a plasma from the processing gas by application of electrical power into the processing chamber, whereby an electrostatic chucking voltage is applied from the time of the start of supply of electrical power to generate the plasma through a prescribed period of time.

In this embodiment, in the electrostatic chucking step, an electrostatic chucking voltage is applied so that the stage potential increases gradually.

In this embodiment, in the plasma generation step, the electrical power supplied is the minimum required for the prescribed processing of the semiconductor substrate.

The above-described aspects of a method for manufacturing a semiconductor device can be appropriately combined, thereby achieving synergy in suppressing the generation of particles.

### BRIEF DESCRIPTION OF THE DRAWINGS

FIG. 1 is a schematic cross-sectional view showing the basic concept of a semiconductor manufacturing apparatus according to a first embodiment of the present invention.

FIG. 2 is a schematic cross-sectional view of a semiconductor manufacturing apparatus, showing a specific example of the concept of the first embodiment.

FIG. 3 is a schematic cross-sectional view of a semiconductor manufacturing apparatus according to a second embodiment of the present invention.

FIG. 4 is a schematic drawing of the approximate distribution of electrostatic potential in the vertical direction during plasma generation within a general semiconductor manufacturing apparatus using plasma.

FIG. 5 is a graph showing the number of generated particles and the time variation of various process signals when prescribed processing is performed of a semiconductor substrate using a method for manufacturing a semiconductor device according to a third embodiment of the present invention.

FIG. 6 is a graph showing the number of generated particles and the time variation of various process signals when prescribed processing is performed of a semiconductor substrate using a method for manufacturing a semiconductor device according to a fourth embodiment of the present invention.

FIG. 7 is a graph showing the time variation in the electrostatic chucking voltage when the electrostatic chucking voltage is applied in a method for manufacturinga semiconductor device according to the fourth embodiment of the present invention.

FIG. 8 is a graph showing the number of generated particles and the time variation of various process signals when prescribed processing is performed of a semiconductor substrate using a method for manufacturing a semiconductor device according to a fifth embodiment of the present invention.

FIG. 9 is a schematic cross-sectional view of a semiconductor manufacturing apparatus according to a sixth embodiment of the present invention.

FIG. 10 is a drawing showing EPMA analysis results for particles generated in a tungsten plasma etching apparatus.

FIG. 11 is a schematic cross-sectional view showing a specific example of the semiconductor manufacturing apparatus of FIG. 9.

FIG. 12 is a schematic cross-sectional view showing a semiconductor manufacturing apparatus according to a seventh embodiment of the present invention.

FIG. 13 is a schematic cross-sectional view showing a specific example of the semiconductor manufacturing apparatus of FIG. 12.

FIG. 14 is a schematic cross-sectional view showing a semiconductor manufacturing apparatus according to an eighth embodiment of the present invention.

FIG. 15 is a schematic cross-sectional view showing a particle monitoring system used for monitoring particles within a semiconductor manufacturing apparatus according to an embodiment of the present invention.

FIG. 16 is a graph showing the number of particles generated when prescribed processing is performed of a semiconductor substrate within a processing chamber, as observed by the particle monitoring system of FIG. 15, and the time variations of various process signals.

FIG. 17 is an image, which captures particles directed toward a semiconductor substrate generated from an area surrounding a semiconductor substrate.

FIG. 18 is a schematic image of a semiconductor manufacturing apparatus of the past.

### DETAILED DESCRIPTION OF THE PREFERRED EMBODIMENTS

Embodiments of the present invention are described in detail below, with references made to relevant accompanying drawings.

In a semiconductor manufacturing apparatus in which prescribed processing is performed of a semiconductor substrate placed on a stage, which is to be subjected to processing, there are cases in which it is necessary to fix the semiconductor substrate in place during the processing. The present invention is a semiconductor manufacturing apparatus directed at suppressing the generation of particles caused by electrostatic stress generated when an electrostatic chucking voltage is applied.

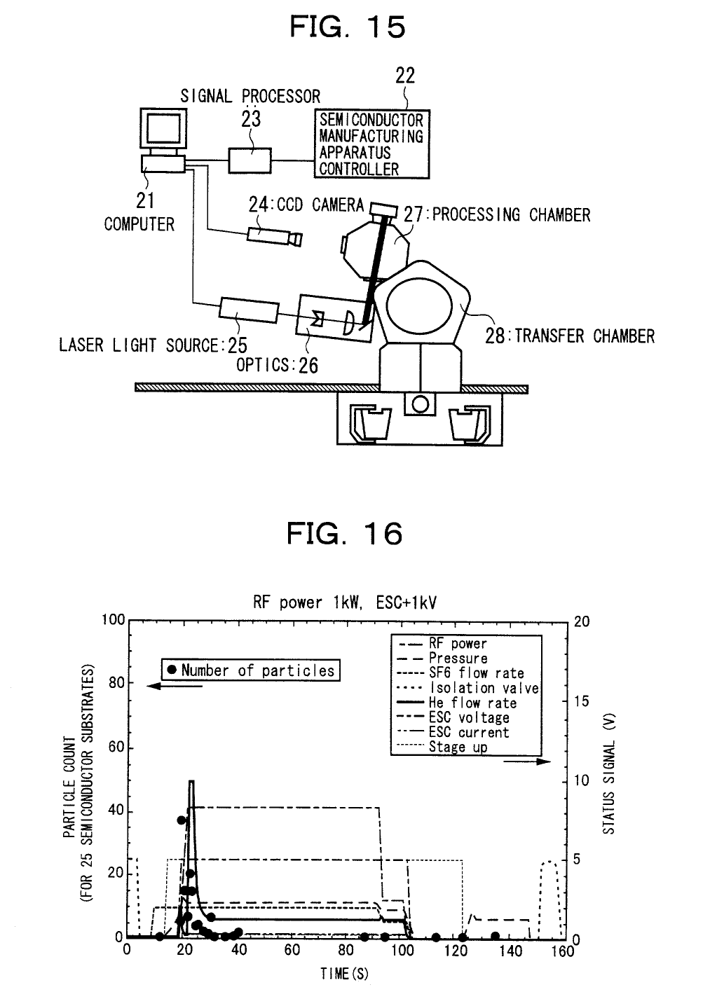

First, observation of particle generation within a processing chamber of such a semiconductor manufacturing apparatus is described below, with references made to FIG. 15 to FIG. 17.

FIG. 15 is a schematic representation of a particle monitoring system used in the particle observations described below. The semiconductor manufacturing apparatus used in these observations has a processing chamber 27 in which processing of a semiconductor substrate is performed, and a transfer chamber 28, which holds the semiconductor substrate that is feed therewithin. The particle monitoring system uses the laser light scattering method, in which laser light from a laser light source 25 via optics 26 so as to illuminate the inside of the processing chamber 27, laser light scattered within the processing chamber 27 being detected by a CCD camera 24, so as to measure the number of particles within the processing chamber 27. Control of the laser light source 25 and processing of the detected signal from the CCD camera 24 are performed by a computer 21. The computer 21 from a semiconductor manufacturing apparatus control panel, via a signal processor 23, signals indicating various process conditions of the semiconductor substrate, such as the RF power used for processing (RF power), the internal chamber pressure (Pressure), the processing gas (sulfur hexafluoride: SF₆) flow (SF6 flow rate), the opening of the gate valve transporting in the semiconductor substrate (Isolation Valve), the flow of helium for cooling (He flow rate), the electrostatic chucking voltage (ESC voltage), the electrostatic chucking current (ESC current), and the stage raised position (Stage Up).

The results of using such a particle monitoring system to monitor the number of particles generated within the processing chamber 27 when prescribed processing is performed of a semiconductor substrate within the processing chamber 27, and the change in the various process signals are shown in FIG. 16. In FIG. 16, the vertical axis on the left indicates the number of particles generated (the overall number after processing 25 semiconductor substrates), and the vertical axis on the right indicates the size of the various status signals indicating the operating condition semiconductor manufacturing apparatus. The black circles in this graph indicate the number of particles and the lines indicate the various status signals. Processing was performed with a RF power of 1 kW, an electrostatic chucking voltage of 1 kV, and a processing time of approximately 160 seconds for each semiconductor substrate.

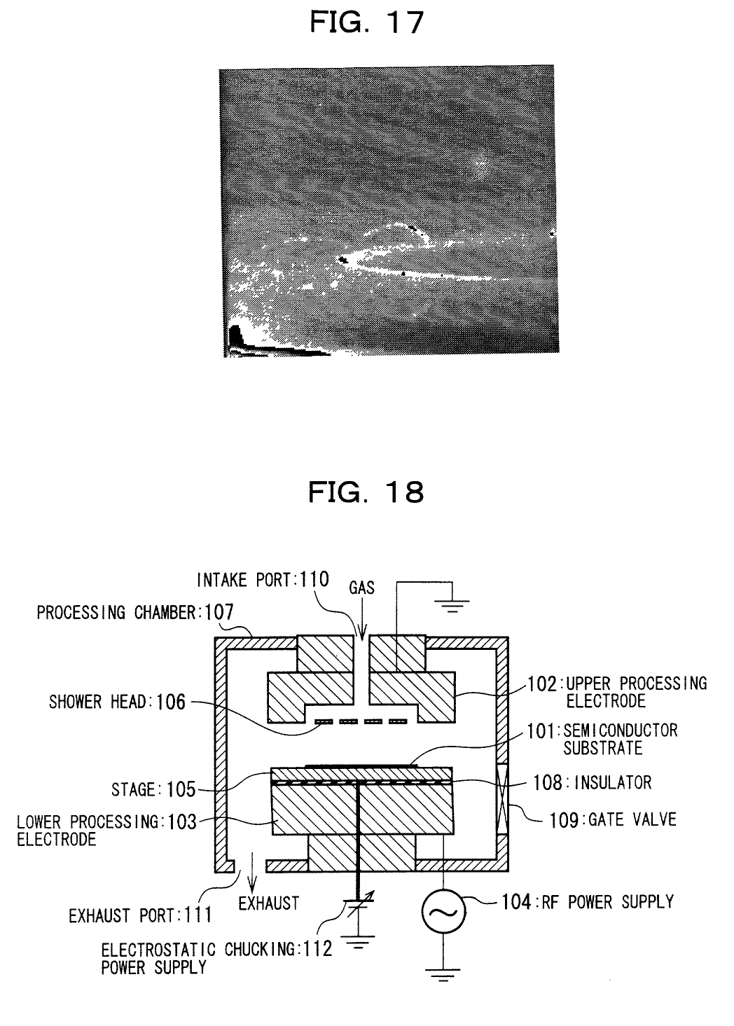

From the results shown in FIG. 16, it can be seen that a relatively large number of particles are generated when an electrostatic chucking voltage is applied. From this fact, it can be envisioned that application of an electrostatic chucking voltage to the stage generates an electrostatic stress on a deposited film or accumulated foreign matter attached to the stage, this stress resulting in the generation of particles. In actuality, as shown in FIG. 17, when an electrostatic chucking voltage is applied, it is possible to observe particles generated from the area surrounding the semiconductor substrate directed at the semiconductor substrate.

The present invention was arrived at from knowledge related to the above-noted generation of particles within the processing chamber of the semiconductor manufacturing apparatus, and presents the proposals as detailed below.

Specifically, the present invention is a semiconductor manufacturing apparatus in, which there is a need to fix a semiconductor substrate in place during processing, wherein the semiconductor substrate is held by a method other than electrostatic chucking.

The present invention provides another method for manufacturing a semiconductor device in which there is a reduction in the generation of particles caused by the application of an electrostatic chucking voltage, this method being one in which consideration is given to the manner in which the electrostatic chucking voltage is applied, or in which consideration is given to a structure in which it is difficult for electrostatic stress to be generated by virtue of the configuration of the area surrounding the substrate, thereby suppressing the electrostatic stress and suppressing the generation of particles.

Embodiments of the present invention indicating specific measures taken are described in detail below, with references made to relevant accompanying drawings.

All the embodiments described below can be applied to a semiconductor manufacturing apparatus such as a plasma CVD apparatus, a plasma etching apparatus, and a plasma sputtering apparatus. Unless specifically indicated to the contrary, the descriptions that follow are for the case of an RF plasma etching apparatus, but it will be understood that these embodiments can be applied as well to other types of semiconductor manufacturing apparatuses.

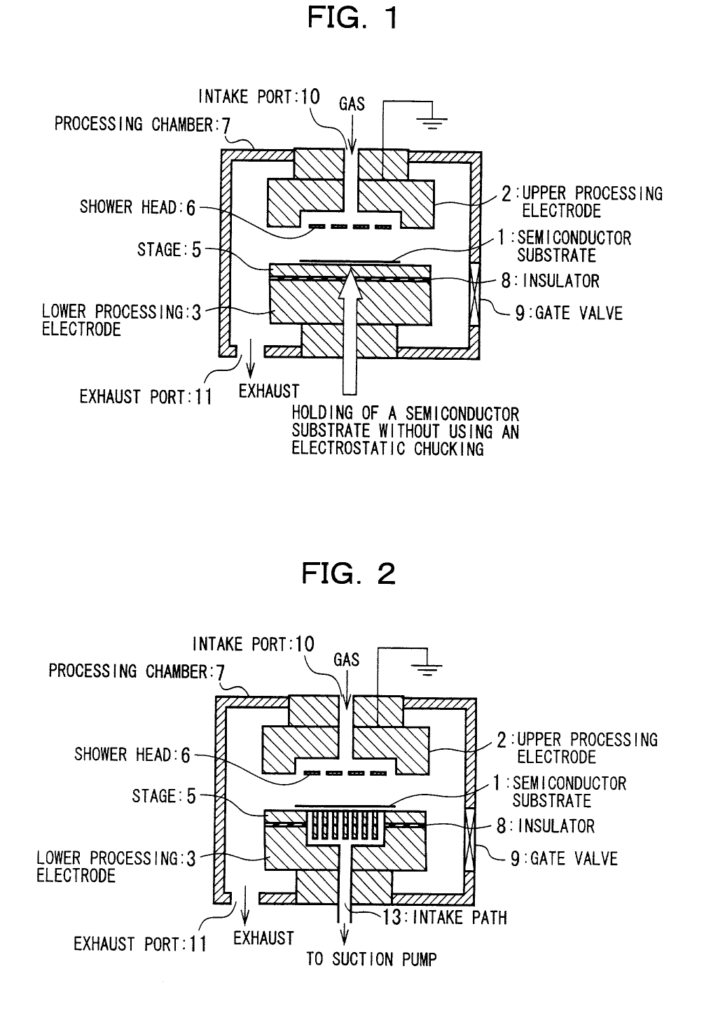

FIG. 1 shows a schematic representation of the basic concept of a semiconductor manufacturing apparatus according to a first embodiment of the present invention.

This embodiment has a processing chamber 7 into which a semiconductor substrate 1 to be processed can be placed, via a gate valve 9. The processing chamber 7 is provided with an intake port 10 for introduction of processing gas such as etching gas or the like, and an exhaust port 11 for exhausting the inside of the processing chamber 7. The path for introduction of the processing gas is disposed between the intake port 10 and the and a location above the semiconductor substrate 1, this being continuous with a shower head 6 having a multitude of apertures across the processed surface, so that processing gas is introduced over the surface being processed in a substantially uniform manner.

An upper processing electrode and a lower processing electrode 3 for the purpose of supplying RF power internally are provided above and below the processing chamber 7. A RF power supply (not shown in the drawing) is connected to the lower processing electrode 3, and the upper processing electrode 2 is grounded. The stage 5, onto which the semiconductor substrate 1 is placed, is provided so as to sandwich an insulator 8 between it and the lower processing electrode 3. The stage 5 can be moved upward and downward to an appropriate position for processing.

In a semiconductor manufacturing apparatus such as noted above, in the case in which electrostatic chucking is to be used as the method for holding the semiconductor substrate on the stage 5, electrostatic stress generated when an electrostatic chucking voltage is applied generates a relatively large number of particles. Because of this situation, rather than using electrostatic chucking, in this embodiment another method is used to fix the semiconductor substrate 1.

If the method of holding the semiconductor substrate 1 used in this embodiment is one that intrinsically does not generate electrostatic stress, any method can be used. A specific example, as shown in FIG. 2, is that in which a suction path 13 is provided, this suction path having an aperture at a location directly below the semiconductor substrate 1, air within the suction path 13 being pulled in by a suction pump, so that the semiconductor substrate is vacuum chucked to the stage 5.

The suction pump used to do this can be a vacuum pump such as a turbo molecular pump, a rotary pump, or a dry pump or the like, this pump having adequate pressure-reducing capacity to sufficiently reduce the internal pressure in the processing chamber during processing.

In this embodiment of the present invention, if the lower surface of the semiconductor substrate 1 is polished to a mirror finish, it is possible to suppress the inflow of air from the space between the semiconductor substrate and the stage 5, thereby enabling reinforcement of the holding force, and achieving good vacuum chucking of the semiconductor substrate 1 with a relative strong holding force. Even if at least the upper surface of the stage 5 is made of a deformable material such as a silicone rubber or the like, it is possible to achieve a good vacuum holding force.

In this embodiment of the present invention, by adopting the method of fixing the semiconductor substrate by vacuum chucking using a suction pump, the need to apply an electrostatic chucking voltage is eliminated, thereby enabling a reduction in the generation of particles without generating an electrostatic stress.

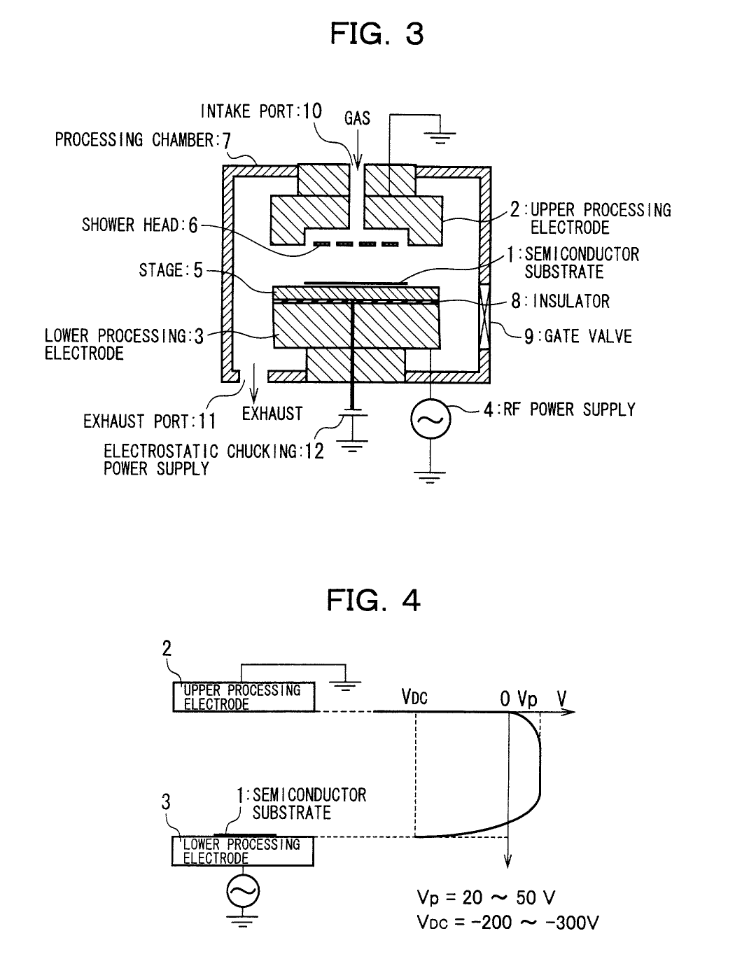

FIG. 3 is a schematic representation of a semiconductor manufacturing apparatus according to a second embodiment of the present invention. In this drawing, elements in common with the first embodiment are assigned the same reference numerals and are not described herein.

In this embodiment, the method of fixing the semiconductor substrate 1, similar to a method of the past, is that of applying a voltage to the stage 5 from an electrostatic chucking power supply 12, so as to fix the semiconductor substrate 1 by electrostatic chucking. In this case, however, the voltage applied to the stage 5 is not positive, but rather negative.

In a semiconductor manufacturing apparatus in which processing of a semiconductor substrate 1 is performed by generation of a plasma, such as shown in FIG. 3, during the generation of the plasma, an electrostatic potential distribution such as shown in FIG. 4 is developed in the vertical direction. That is, in the region of the upper processing electrode 2, which is grounded, the potential is substantially 0 (ground), and in the region of the lower processing electrode 3, to which an RF voltage is applied, the potential is negative, a positive potential being developed in the region in which a plasma is generated between the upper processing electrode 2 and the lower processing electrode 3. In a typical semiconductor manufacturing apparatus, the maximum value of negative voltage V_{DC} applied in the region of the lower processing electrode 3 is approximately −200 to −300 volts, and the maximum value of positive voltage Vp in the plasma generation region is approximately 20 to 50 volts. In response to such an electrostatic potential, the semiconductor substrate 1 develops a self-bias as described above.

By applying a potential with a given difference with respect to the potential of the semiconductor substrate 1 that is being electrostatically chucked, it is possible to achieve electrostatic chucking by generation of an electrostatic force between the stage 5 and the semiconductor substrate 1. This being the case, the electrostatic chucking of the semiconductor substrate 1 at which a negative self-bias is developed makes it possible, without applying a positive potential to the stage 5, to implement the embodiment by applying a negative voltage having a given difference with respect to the self-bias potential.

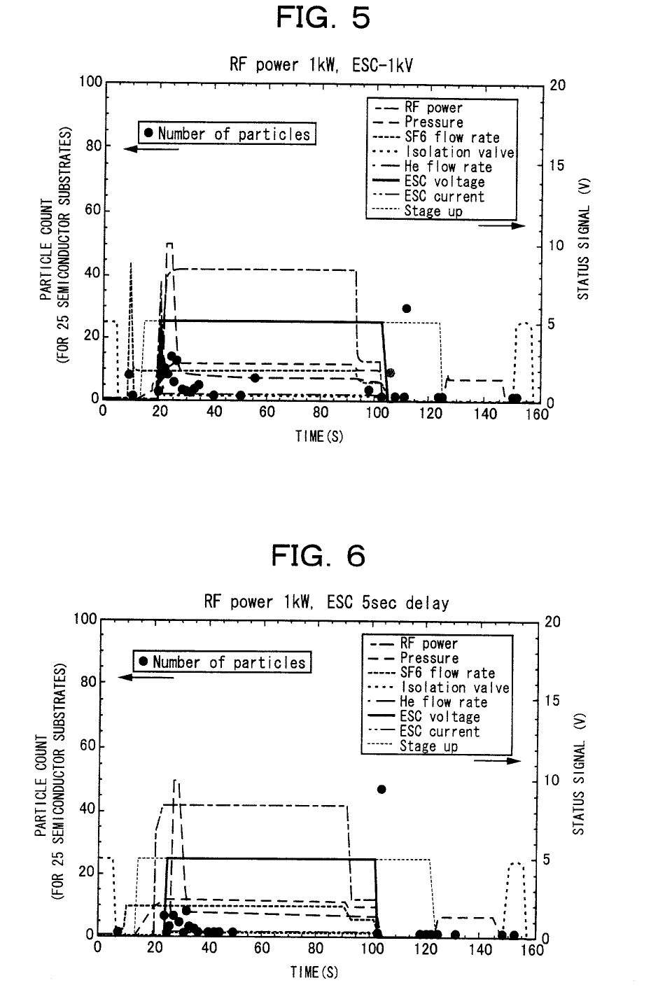

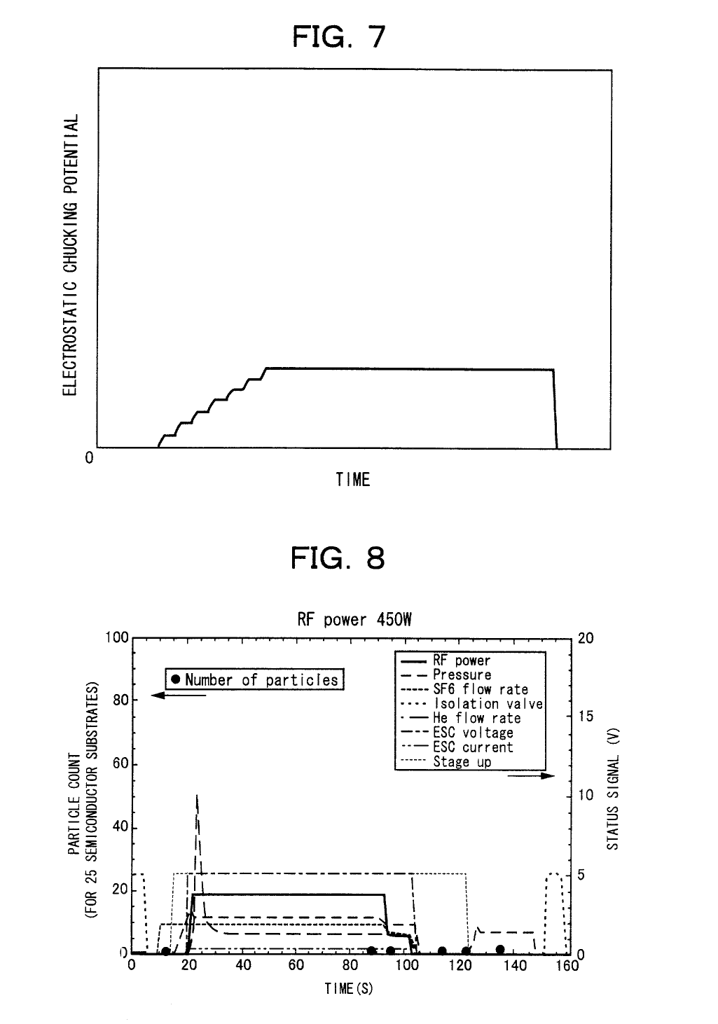

FIG. 5 shows the results of monitoring the number of particles and the variations in various process signals when prescribed processing is performed of a semiconductor substrate, with an RF power of 1 kW, an electrostatic chucking voltage of −1 kV, and a processing time of approximately 160 seconds per semiconductor substrate 1.

From the results shown in FIG. 5, it can be seen that, compared to the case in which the electrostatic chucking voltage is 1 kV, if the electrostatic chucking voltage is −1 kV the number of particles generated is suppressed to a low level. In this manner, it can be seen experimentally that in the case in which the electrostatic chucking voltage is made a relatively large positive potential, a relatively large number of particles are generated. Thus, it is possible by making the electrostatic chucking voltage a negative potential to suppress the generation of particles.

Even in the case in which the electrostatic chucking voltage is a positive potential, it is possible to suppress the level of particles generated to a relatively low level by making the value thereof as small as possible. That is, by making the electrostatic chucking voltage value as close as possible to the self-bias potential, it is possible to suppress generation of electrostatic stress occurring when the electrostatic chucking voltage is applied. Given this, it is desirable that the electrostatic chucking voltage be made as close as possible to the self-bias potential, and within a range that enables sufficient electrostatic suction holding.

Although the results shown in FIG. 16 and FIG. 5 are both experimental results obtained using an RF power of 1 kW for generating a plasma, the same type of results are obtained even if the RF power is changed.

In a third embodiment of the present invention, it is possible to suppress particle generation by giving consideration to the timing of application of the electrostatic chucking voltage.

In a conventional method for manufacturing a semiconductor device shown in FIG. 16, the RF power is applied simultaneously with the application of the electrostatic chucking voltage. In contrast to this approach, the inventors discovered that it is possible to suppress the generation of particles by applying the electrostatic chucking voltage with a timing that is slightly delayed with respect to the application of RF power. In this case, in the region of the semiconductor substrate, a self-bias potential is first developed at the surface of the semiconductor substrate, after which the electrostatic chucking voltage is developed.

FIG. 6 shows the results monitoring the number of particles generated and the variation in various process signals, with the electrostatic chucking voltage applied 5 seconds after application of the RF power, prescribed processing of the semiconductor substrate being performed with other conditions being the same as shown in the case of FIG. 16. From the results shown in FIG. 6, it can be seen that, compared to the results shown in FIG. 16, there is further suppression of the number of generated particles.

As described above, by delaying the timing of the application of the electrostatic chucking voltage with respect to the application of RF power, it is possible to suppress the generation of particles. In doing this, with regard to the delay time in the application of the electrostatic chucking voltage, it is desirable that the timing of the application of the electrostatic chucking voltage be made an appropriately, so as to minimize the generation of particles, within a range that does not cause a problems such as the semiconductor substrate moving.

A fourth embodiment of the present invention is a method for suppressing the generation of particles in which consideration is given to the method of applying the voltage at the start of application of the electrostatic chucking voltage.

In the general method for manufacturing a semiconductor device shown in FIG. 16, a DC voltage is applied instantaneously as the electrostatic chucking voltage, the voltage on the electrostatic chuck reaching a prescribed voltage value in less than 1 second. In such cases, a sudden change occurs at the boundary surrounding the semiconductor substrate. As a result of this sudden change at this boundary, a great stress is suddenly applied to a deposited film or foreign matter in the area surround the semiconductor substrate, thereby encouraging the generation of particles.

Given the above, this embodiment applies the electrostatic chucking voltage so that it is increased in step-wise fashion. As a result, it is possible to suppress the generation of particles.

In this embodiment of the present invention, the electrostatic chucking voltage is applied so that it is increased in step-wise fashion, is alternatively possible to apply the voltage so that it increases continuously.

In a fifth embodiment of the present invention, the generation of particles is suppressed by making the RF power for plasma generation small.

In contrast to FIG. 16, in which processing is performed with 1 kW of RF power applied, FIG. 8 shows the results of monitoring the number of generated particles and variations in various process signals in the fifth embodiment, with prescribed processing of the semiconductor substrate performed with just 450 W of RF power applied. From the results shown in FIG. 8 it can be seen that, compared with the results of FIG. 16, there is a further suppression of particle generation.

In this manner, the generation of particles attributed to electrostatic stress occurring when an electrostatic chucking voltage is applied tends to occur when the RF power is high, and tends to be suppressed when the RF power is made small.

If the RF power is made small, because it can be envisioned that such effects on the manufacturing process as a reduction in the processing rate, such as a reduction in etching and deposition rates, will occur, it is necessary to adjust condition parameters other than the RF power as appropriate.

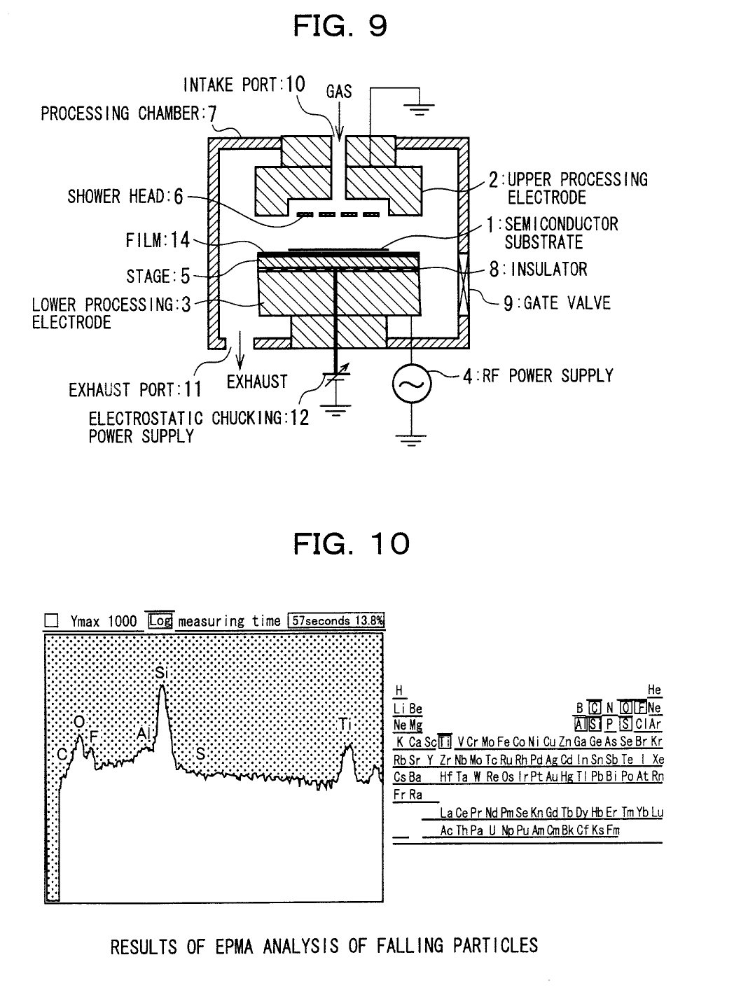

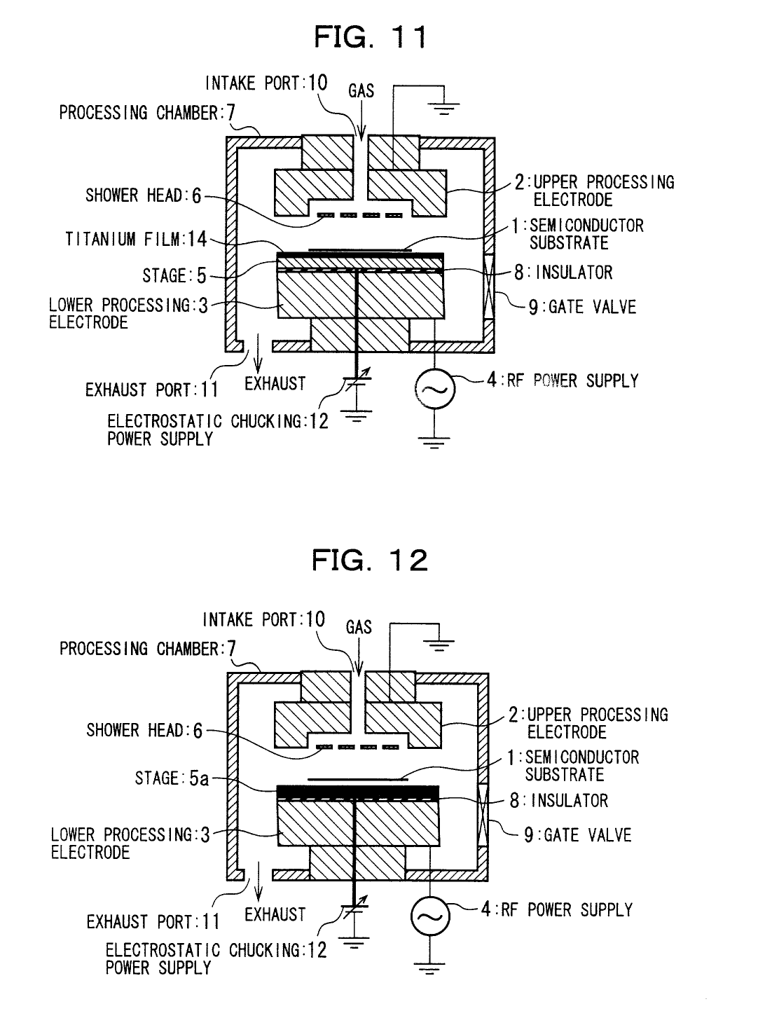

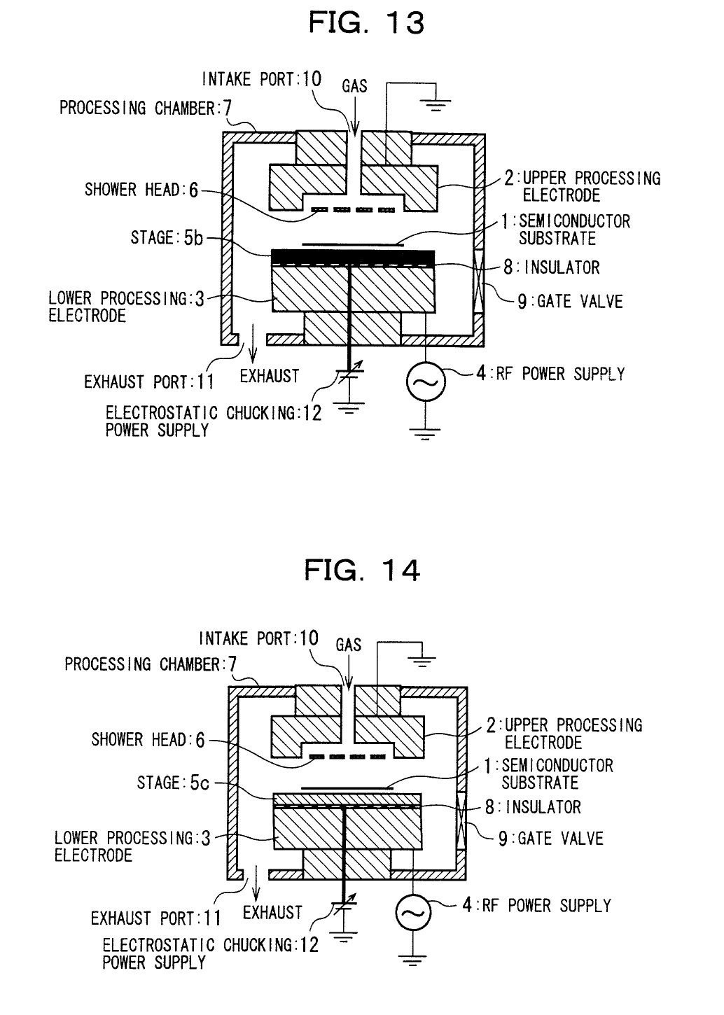

A sixth embodiment of the present invention is shown in the schematic cross-sectional view of a semiconductor manufacturing apparatus shown in FIG. 9. In FIG. 9, elements in common with the first and the second embodiments are assigned the same reference numerals and are not described herein.

In this embodiment, a film 14 made from a substance having a composition substantially the same as the generated particles is formed on a surface of the stage 5. The electrostatic stress generated when an electrostatic chucking voltage is applied to the stage 5 is generated by a difference in dielectric constants between the stage 5 and a deposited film or foreign matter attached thereto. This being the case, by providing the film 14, made of a substance having a composition substantially the same as a deposited film or foreign matter attached to the stage 5 on the surface of the stage 5, it is possible to reduce the electrostatic stress to which the deposited film and foreign matter are subjected, thereby suppressing the generation of particles.

Although this embodiment is described for the example in which the film 14 is formed on the stage 5, in the case in which surrounding material such as a ceramic ring is disposed in the region of the semiconductor substrate 1, it is desirable that the film 14 also be provided on the peripheral component.

FIG. 10 shows the results of analyzing particles generated in tungsten plasma etching apparatus, as a specific example of this embodiment of the present invention, using an EPMA (electron probe microanalyzer). From these results, it can be seen that particles generated in this plasma etching apparatus include a large amount of titanium. Given this, it is possible to reduce the generation of particles by forming a titanium film 14 on the stage 5.

FIG. 12 is a schematic cross-sectional view showing a semiconductor manufacturing apparatus according to a sixth embodiment of the present invention. In FIG. 12, elements in common with the first, second, and sixth embodiments of the present invention are assigned the same reference numerals and are not described herein.

In a semiconductor manufacturing apparatus according to the sixth embodiment, a stage 5a is made of a substance having substantially the same composition as the generated particles. By adopting a configuration in which the material in the area surrounding the semiconductor substrate 1 has a composition that is substantially the same as the generated particles, similar to the case of the sixth embodiment, the difference in dielectric constant between the stage 5a and a deposited film or foreign matter attached to the stage 5a as particles is eliminated, thereby enabling a reduction in the electrostatic stress applied to the deposited film or foreign matter when applying an electrostatic chucking voltage to the stage 5a, which enables a reduction in the number of generated particles.

Similar to the case of the sixth embodiment, in a tungsten plasma etching apparatus in particular, because the generated particles contain a large amount of titanium, by making the stage 5b of titanium, it is possible to suppress the generation of particles.

FIG. 14 is a schematic cross-sectional view showing a semiconductor manufacturing apparatus according to an eighth embodiment of the present invention, in which elements in common with the first, second, sixth, and seventh embodiments are assigned the same reference numerals and are not described herein.

In the semiconductor manufacturing apparatus according to this embodiment, minimally the surface of the stage 5c is made a material having substantially the same dielectric constant as the generated particles. The electrostatic stress applied to a deposited film or foreign matter when an electrostatic chucking voltage is applied to the stage 5c, as described above, is generated because of the difference in dielectric constant between the deposited film and the stage. Thus, even if it is a different material from the deposited film or foreign matter, as long as a film made of a material having substantially the same dielectric constant is used at least in the area surrounding the semiconductor substrate, it is possible to suppress the generation of electrostatic stress, thereby reducing the generation of particles.

In a semiconductor manufacturing apparatus in which it is necessary to fix in place a semiconductor substrate to be processed and having a configuration as described in detail above, by adopting a configuration in which the semiconductor substrate is vacuum chucked in place, it is possible to reduce the generation of particles, which have an adverse affect on the processing of the semiconductor substrate, without performing electrostatic chucking that causes electrostatic stress on a deposited film in the area surrounding the semiconductor substrate.

Additionally, in a semiconductor manufacturing apparatus in which a semiconductor substrate is fixed in place by electrostatic chucking, by taking precautions with the manner in which the electrostatic chucking potential is applied, and with the configuration of the area surrounding the semiconductor substrate, it is possible to reduce the electrostatic stress applied to a deposited film or the like, and to reduce the generation of particles.

What is claimed is:

1. A semiconductor manufacturing apparatus comprising:
a processing chamber, which is substantially hermetically sealable in order to maintain a clean condition therewithin;
a stage disposed within said processing chamber, on which is placed a semiconductor substrate that is to be subjected to processing, wherein the semiconductor substrate is fixed on the stage when it is subjected to prescribed processing;
a suction path with an aperture located within a region on said stage directly below said semiconductor substrate when as semiconductor substrate is placed thereon; and
a suction pump connected to said suction path and capable of reducing a pressure within said suction path to a pressure that is lower than a pressure within said processing chamber during processing.

2. A semiconductor manufacturing apparatus comprising:
a processing chamber, which is substantially hermetically sealable in order to maintain a clean condition therewithin;
a stage disposed within said processing chamber, on which is placed a semiconductor substrate that is to be subjected to processing;
an electrostatic chucking power supply applying an electrostatic chucking voltage to said stage so as to generate an electrostatic force, which fixes in place said semiconductor substrate onto said stage, wherein said electrostatic chucking power supply applies an electrostatic chucking voltage that is close to a potential of said semiconductor substrate being processed and within a range of voltage that enables suction chucking of said semiconductor substrate to said stage by desired electrostatic force.

3. A semiconductor manufacturing apparatus according to claim 2, wherein said electrostatic chucking power supply applies a negative electrostatic chucking voltage.

4. A semiconductor manufacturing apparatus comprising:
a processing chamber, which is substantially hermetically sealable in order to maintain a clean condition therewithin;
a stage disposed within said processing chamber, on which is placed a semiconductor substrate that is to be subjected to processing;
an electrostatic chucking power supply applying an electrostatic chucking voltage to said stage so as to generate an electrostatic force, which fixes in place said semiconductor substrate onto said stage;
a processing gas introduction means for introducing a processing gas to within said processing chamber;
a lower processing electrode disposed at a bottom part of said processing chamber;
an upper processing electrode disposed in opposition to said lower processing electrode at a top part of said processing chamber; and
a controller performing control so that an electrostatic chucking voltage is applied at a time when a prescribed amount of time had passed after a start of application of electrical power for generating a plasma.

5. A semiconductor manufacturing apparatus according to claim 2, comprising:
means for introducing a processing gas to within said processing chamber;
a lower processing electrode disposed at a bottom part of said processing chamber and for applying an electrical power sufficient to generate plasma from said processing gas;
an upper processing electrode disposed in opposition to said lower processing electrode at a top part of said processing chamber; and
a controller performing control so that said electrostatic chucking power supply applies an electrostatic chucking voltage at a time when a prescribed amount of time had passed after a start of application of electrical power for generating a plasma.

6. A semiconductor manufacturing apparatus comprising:
a processing chamber, which is substantially hermetically sealable in order to maintain a clean condition therewithin;
a stage disposed within said processing chamber, on which is placed a semiconductor substrate that is to be subjected to processing;
an electrostatic chucking power supply applying an electrostatic chucking voltage to said stage so as to generate an electrostatic force, which fixes in place said semiconductor substrate onto said stage; and
a controller performing control so that said electrostatic chucking voltage is applied so that a potential of said stage is gradually raised.

7. A semiconductor manufacturing apparatus according to claim 2, further comprising a controller performing control so that said electrostatic chucking voltage is applied so that a potential of said stage is gradually raised.

8. A semiconductor manufacturing apparatus according to claim 2, comprising:
means for introducing a processing gas to within said processing chamber;
a lower processing electrode disposed at a bottom part of said processing chamber and for supplying an electric power to generate plasma from said processing gas; and
an upper processing electrode disposed in opposition to said lower processing electrode at a top part of said processing chamber, wherein
an amount of electrical power generating a plasma is the minimum amount of electrical power required to perform prescribed processing of said semiconductor substrate.

9. A semiconductor manufacturing apparatus comprising:
a processing chamber, which is substantially hermetically sealable in order to maintain a clean condition therewithin;
a stage disposed within said processing chamber, on which is placed a semiconductor substrate that is to be subjected to processing; and
an electrostatic chucking power supply applying an electrostatic chucking voltage to said stage so as to generate an electrostatic force, which fixes in place said semiconductor substrate onto said stage, wherein
a film having a composition substantially the same as a composition of a particle that is expected to be generated is formed on a surface of said stage.

10. A semiconductor manufacturing apparatus according to claim 2, wherein a film having a composition substantially the same as a composition of a particle that is expected to be generated is formed on a surface of said stage.

11. A semiconductor manufacturing apparatus according to claim 9, said semiconductor manufacturing apparatus performing a tungsten plasma etching process, wherein a material of said film is titanium.

12. A semiconductor manufacturing apparatus comprising:
a processing chamber, which is substantially hermetically sealable in order to maintain a clean condition therewithin;
a stage disposed within said processing chamber, on which is placed a semiconductor substrate that is to be subjected to processing; and
an electrostatic chucking power supply applying an electrostatic chucking voltage to said stage so as to generate an electrostatic force, which fixes in place said semiconductor substrate onto said stage, wherein
a material of said stage has a composition substantially the same as a particle that is expected to be generated.

13. A semiconductor manufacturing apparatus according to claim 2, wherein a material of said stage has a composition substantially the same as a particle that is expected to be generated.

14. A semiconductor manufacturing apparatus according to claim 12, wherein said semiconductor manufacturing apparatus performing a tungsten plasma etching process, and wherein a material of said stage is titanium.

15. A semiconductor manufacturing apparatus comprising:
a processing chamber, which is substantially hermetically sealable in order to maintain a clean condition therewithin;
a stage disposed within said processing chamber, on which is placed a semiconductor substrate that is to be subjected to processing; and
an electrostatic chucking power supply applying an electrostatic chucking voltage to said stage so as to generate an electrostatic force, which fixes in place said semiconductor substrate onto said stage, wherein
minimally a material of a surface of said stage has a material having a dielectric constant substantially the same as a dielectric constant of a particle that is expected to be generated.

16. A semiconductor manufacturing apparatus according to claim 2, wherein a material of at least a surface of said stage is a material having a dielectric constant substantially the same as a dielectric constant of a particle that it is expected to be generated.

17. A method for manufacturing a semiconductor device comprising:
a step of placing a semiconductor substrate onto a stage within a processing chamber that can be substantially hermetically sealed in order to maintain a clean condition therewithin; and
a step of performing electrostatic chucking of said semiconductor substrate onto said stage, by applying a prescribed electrostatic chucking voltage to said stage, wherein
in said electrostatic chucking step a electrostatic chucking voltage as close as possible to a potential of said semiconductor substrate being processed and within a voltage that enables suction chucking of said semiconductor substrate onto said stage is applied during processing.

18. A method for manufacturing a semiconductor device according to claim 17, wherein said electrostatic chucking voltage is a negative voltage.

19. A method for manufacturing a semiconductor device comprising:
a step of placing a semiconductor substrate onto a stage within a processing chamber that can be substantially hermetically sealed in order to maintain a clean condition therewithin;
a step of introducing a processing gas into within said processing chamber;
a step of generating a plasma from said processing gas by application of RF power within said processing chamber; and
a step of performing electrostatic chucking of said semiconductor substrate onto said stage, by applying a prescribed electrostatic chucking voltage to said stage, wherein
said electrostatic chucking voltage is applied at a time when a prescribed amount of time had passed after a start of application of said RF power for generating said plasma.

20. A method for manufacturing a semiconductor device according to claim 17, further comprising:
a step of introducing a processing gas into within said processing chamber; and
a step of generating a plasma from said processing gas by application of RF power within said processing chamber; wherein
said electrostatic chucking voltage is applied at a time when a prescribed amount of time had passed after a start of application of said RF power for generating said plasma.

21. A method for manufacturing a semiconductor device comprising:
a step of placing a semiconductor substrate onto a stage within a processing chamber that can be substantially hermetically sealed in order to maintain a clean condition therewithin; and
a step of performing electrostatic chucking of said semiconductor substrate onto said stage, by applying a prescribed electrostatic chucking voltage to said stage, wherein
in said electrostatic chucking step said electrostatic chucking voltage is applied so that a potential of said stage is gradually increased.

22. A method for manufacturing a semiconductor device according to claim 17, wherein in said electrostatic chucking step said electrostatic chucking voltage is applied so that a potential of said stage is gradually increased.

23. A method for manufacturing a semiconductor device according to claim 17, comprising:
a step of introducing a processing gas into within said processing chamber; and
a step of generating a plasma from said processing gas by applying RF power within said processing chamber; wherein
said plasma generation step is performed with the minimum power required to perform prescribed processing of said semiconductor substrate.
